(19) United States
(12) Patent Application Publication
(10) Pub. No.: US 2026/0237453 A1
(43) Pub. Date: Aug. 13, 2026

(54) METHOD OF SETTING SIGNAL DRIVE STRENGTH OF STORAGE

(71) Applicant: ATP ELECTRONICS TAIWAN INC., Taipei City (TW)

(72) Inventors: Mau Jung LU, Taipei City (TW); Min Jung CHU, Taipei City (TW)

(73) Assignee: ATP ELECTRONICS TAIWAN INC., Taipei City (TW)

(21) Appl. No.: 19/341,598

(22) Filed: Sep. 26, 2025

(30) Foreign Application Priority Data
Feb. 8, 2025 (TW) 114104751

(51) Int. Cl. G11C 29/56

(52) U.S. Cl. CPC G11C 29/56012; G11C 29/56008; G11C 29/56016

(57) ABSTRACT

A method of setting a signal drive strength of a storage includes steps of: for each of multiple predefined driving levels, executing a test procedure that includes implementing signal delay, determining a maximum delay value and a minimum delay value, and obtaining a difference between the maximum delay value and the minimum delay value; according to the differences that are obtained respectively for the predefined driving levels, selecting one of the predefined driving levels as an optimal driving level that corresponds to a greatest one of the differences; and setting the signal drive strength of the storage to the optimal driving level thus selected.

### CROSS-REFERENCE TO RELATED APPLICATION

This application claims priority to Taiwanese Invention Patent Application No. 114104751, filed on February 8, 2025, the entire disclosure of which is incorporated by reference herein.

### FIELD

The disclosure relates to a method of setting a signal drive strength of a storage to one of multiple predefined driving levels.

### BACKGROUND

A signal drive strength of a storage is deeply related to overall performance of the storage, and an appropriate signal drive strength may help enhance operational stability and reduce power consumption. In order to satisfy various layout and routing requirements for different printed circuit boards (PCBs), a storage usually includes a storage controller and a storage medium (e.g., flash memory) that support an adjustable signal drive strength, i.e., the signal drive strength of the storage is allowed to be adjusted to one of multiple predefined driving levels.

However, a temperature of a workplace of the storage often changes, i.e., rises or falls, over time, and such temperature fluctuation may cause shifts in operation timing of signaling between the storage controller and the storage medium, and may distort a waveform of a high-speed signal used in the storage. In particular, a rise time and a fall time of a signal change as temperature changes, resulting in instability of signal transmission.

### SUMMARY

Therefore, an object of the disclosure is to provide a method of setting a signal drive strength of a storage to one of multiple predefined driving levels that can alleviate at least one of the drawbacks of the prior art.

According to the disclosure, the method is adapted to be implemented by the storage. The method includes steps of:

for each of the predefined driving levels, executing a test procedure that includes

implementing signal delay by changing a phase of a clock signal based on a plurality of delay values,

determining a maximum delay value that is used to change the phase of the clock signal according to which the storage correctly implements data-writing and data-reading,

determining a minimum delay value that is used to change the phase of the clock signal according to which the storage correctly implements data-writing and data-reading, and

obtain a difference between the maximum delay value and the minimum delay value;

according to the differences that are obtained respectively for the predefined driving levels, selecting one of the predefined driving levels as an optimal driving level that corresponds to a greatest one of the differences; and

setting the signal drive strength of the storage to the optimal driving level thus selected.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 is a block diagram illustrating a storage according to an embodiment of the disclosure.

FIGS. 2 and 3 are flow charts cooperatively illustrating a method of setting a signal drive strength of the storage to one of multiple predefined driving levels according to an embodiment of the disclosure.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

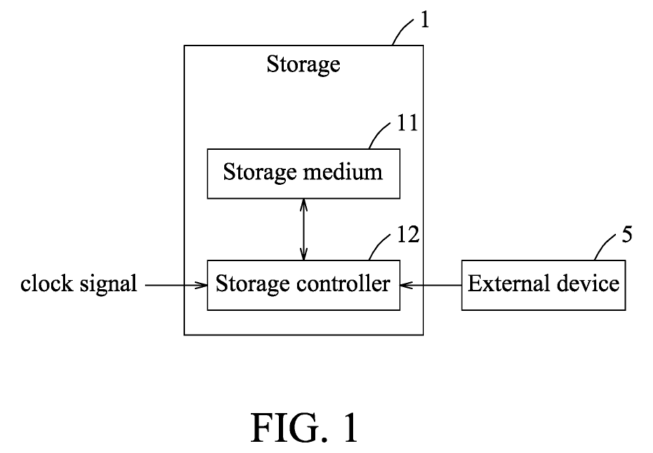

Referring to FIG. 1, an embodiment of a storage 1 according to the disclosure is illustrated. The storage 1 includes a storage controller 12, and a storage medium 11 that is electrically connected to the storage controller 12.

In this embodiment, the storage 1 is implemented by a solid-state drive (SSD), and the storage medium 11 is implemented to be NAND flash, but implementations thereof are not limited to the disclosure herein and may vary in other embodiments. The storage controller 12 may be implemented by any circuit configurable/programmable in a software manner and/or hardware manner to implement functionalities discussed in this disclosure.

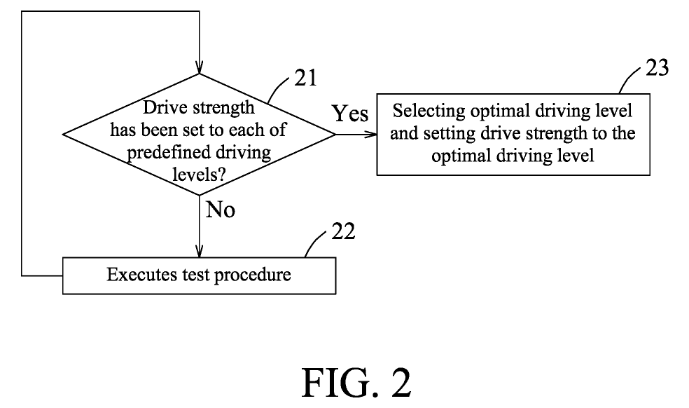

Referring to FIG. 2, an embodiment of a method of setting a signal drive strength of the storage 1 to one of multiple predefined driving levels according to the disclosure is illustrated. The method is adapted to be implemented by the storage controller 12 of the storage 1 that is previously described. The storage controller 12 has the signal drive strength, and is configured to communicate with an external device 5 with the signal drive strength. The external device 5 may be a memory tester, a personal computer, a combination of a processor and a memory device, and so on. Since implementation of the external device 5 has been well known to one skilled in the relevant art, detailed explanation of the same is omitted herein for the sake of brevity. In addition, the storage controller 12 receives a clock signal. In this embodiment, the clock signal is generated by a clock outside of the storage 1, but is not limited thereto. The method includes steps 21 to 23 delineated below. It should be noted that steps 21 and 22 are executed for each of the predefined driving levels.

In step 21, the storage controller 12 determines whether the signal drive strength has been set to each of the predefined driving levels. In response to determining that the signal drive strength has not been set to each of the predefined driving levels, a procedure flow of the method proceeds to step 22. On the other hand, in response to determining that the signal drive strength has been set to each of the predefined driving levels, the procedure flow proceeds to step 23.

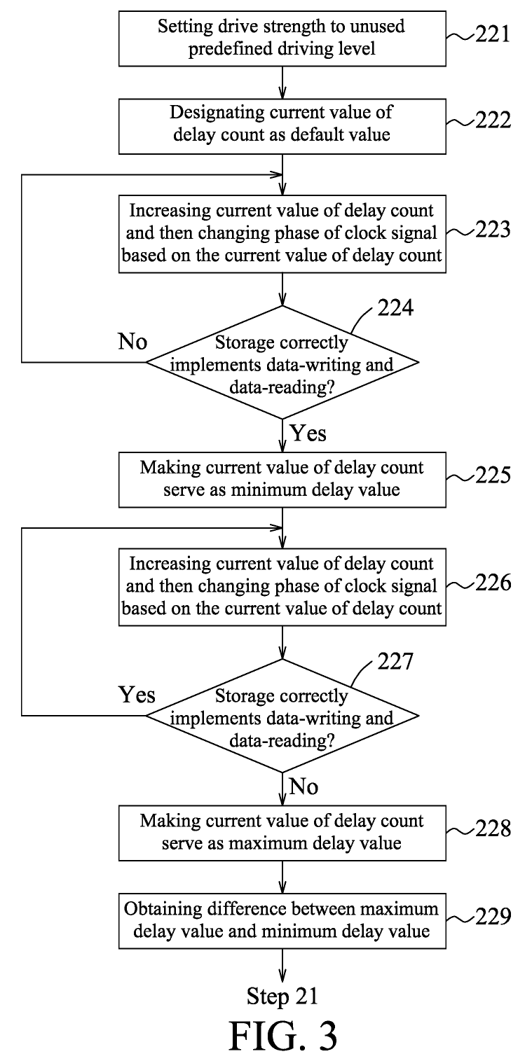

In step 22, for each of the predefined driving levels, the storage controller 12 executes a test procedure to implement signal delay by changing a phase of the clock signal based on a plurality of delay values, to determine a maximum delay value that is used to change the phase of the clock signal according to which the storage 1 correctly implements data-writing and data-reading, to determine a minimum delay value that is used to change the phase of the clock signal according to which the storage 1 correctly implements data-writing and data-reading, and to obtain a difference between the maximum delay value and the minimum delay value. It is worthy of note that the storage controller 12 includes a delay-locked loop (DLL), and uses the plurality of delay values to set the DLL for changing the phase of the clock signal. Specifically, step 22 includes sub-steps 221 to 229 as shown in FIG. 3 and delineated below.

In sub-step 221, the storage controller 12 sets the signal drive strength to an unused one of the predefined driving levels to which the signal drive strength has not been set.

In one embodiment, the predefined driving levels are sequentially arranged in an ascending order, and the storage controller 12 sets the signal drive strength to the unused one of the predefined driving levels to which the signal drive strength has not been set and which is a lowest one of the predefined driving levels in the ascending order. In this embodiment, the step of determining whether the signal drive strength has been set to each of the predefined driving levels may be omitted.

In one embodiment, the predefined driving levels are sequentially arranged in a descending order, and the storage controller 12 sets the signal drive strength to the unused one of the predefined driving levels to which the signal drive strength has not been set and which is a highest one of the predefined driving levels in the descending order. In this embodiment, the step of determining whether the signal drive strength has been set to each of the predefined driving levels may be omitted.

In sub-step 222, after setting the signal drive strength to the unused one of the predefined driving levels, the storage controller 12 designates a current value of a delay count as a default value that is not less than zero. In this embodiment, the default value is zero, but is not limited thereto. For example, in some embodiments, the default value is a positive value for accelerating a process of the method.

In sub-step 223, the storage controller 12 increases the current value of the delay count and then changes the phase of the clock signal based on the current value of the delay count. In this embodiment, the storage controller 12 increases the current value of the delay count by one. However, a quantity of increase to the current value of the delay count is not limited to the disclosure herein and may vary in other embodiments.

In sub-step 224, the storage controller 12 determines whether or not the storage controller 12 correctly implements data-writing into the storage medium 11 and data-reading from the storage medium 11 according to the clock signal. In response to determining that the storage controller 12 does not correctly implement data-writing into the storage medium 11 and data-reading from the storage medium 11 according to the clock signal, sub-steps 223 and 224 are repeated. Contrarily, in response to determining that the storage controller 12 correctly implements data-writing into the storage medium 11 and data-reading from the storage medium 11 according to the clock signal, the procedure flow proceeds to sub-step 225.

Specifically, the storage controller 12 obtains test data from the external device 5 with the signal drive strength of the predefined driving level, performs a memory test on the storage medium 11 based on the test data to obtain a total number of error bits that have occurred during data-writing and data-reading by the storage controller 12 according to the clock signal, and determines whether the total number of error bits is greater than a predefined threshold. In this embodiment, the predefined threshold is zero, but is not limited thereto. The memory test may be implemented by a memory test algorithm such as a March C- algorithm, a March C+ algorithm, a March X/Y algorithm, a March SS algorithm, and so on. Since implementation of the memory test algorithm has been well known to one skilled in the relevant art, detailed explanation of the same is omitted herein for the sake of brevity. In response to determining that the total number of error bits is not greater than the predefined threshold, the storage controller 12 determines that data-writing into the storage medium 11 and data-reading from the storage medium 11 are correctly implemented. In response to determining that the total number of error bits is greater than the predefined threshold, the storage controller 12 determines that data-writing into the storage medium 11 and data-reading from the storage medium 11 are not correctly implemented.

In sub-step 225, the storage controller 12 makes the current value of the delay count that is currently obtained in sub-step 224 serve as the minimum delay value.

In sub-step 226, the storage controller 12 increases the current value of the delay count, and then changes the phase of the clock signal based on the current value of the delay count. Likewise, in this embodiment, the storage controller 12 increases the current value of the delay count by one. However, a quantity of increase to the current value of the delay count is not limited to the disclosure herein and may vary in other embodiments. In some embodiments, the current value of the delay count in each of sub-steps 223 and 226 is increased by a positive value for accelerating the process of the method.

In sub-step 227, the storage controller 12 determines whether or not the storage controller 12 correctly implements data-writing into the storage medium 11 and data-reading from the storage medium 11 according to the clock signal. In response to determining that the storage controller 12 correctly implements data-writing into the storage medium 11 and data-reading from the storage medium 11 according to the clock signal, sub-steps 226 and 227 are repeated. Otherwise, in response to determining that the storage controller 12 does not correctly implement data-writing into the storage medium 11 and data-reading from the storage medium 11 according to the clock signal, the procedure flow proceeds to sub-step 228. Since the way of determining whether or not the storage controller 12 correctly implements data-writing into the storage medium 11 and data-reading from the storage medium 11 according to the clock signal has been described in sub-step 224, detailed explanation of the same is omitted herein for the sake of brevity.

In sub-step 228, the storage controller 12 makes the current value of the delay count that was obtained in last execution of the sub-step 226 serve as the maximum delay value.

In sub-step 229, the storage controller 12 calculates the difference between the maximum delay value and the minimum delay value.

It is worthy of note that for each of the predefined driving levels, the current values of the delay count repeatedly obtained in sub-steps 223 and 226 are the plurality of delay values previously mentioned in step 22. Moreover, the clock signal that is performed with signal delay based on any delay value falling within a range from the maximum delay value to the minimum delay value allows the storage controller 12 to correctly implement data-writing into the storage medium 11 and data-reading from the storage medium 11. Thus, the wider the range from the maximum delay value to the minimum delay value (i.e., the greater the difference between the maximum delay value and the minimum delay value), the more robust the storage 1 is against shifts in operation timing of signaling.

In step 23, according to the differences that are obtained in step 22 respectively for the predefined driving levels, the storage controller 12 selects one of the predefined driving levels as an optimal driving level that corresponds to a greatest one of the differences, and sets the signal drive strength of the storage 1 (i.e., the signal drive strength of the storage controller 12) to the optimal driving level thus selected. Then, the storage controller 12 would communicate with the external device 5 with the signal drive strength thus set. Moreover, the storage controller 12 determines a reference delay value based on the maximum delay value and the minimum delay value that correspond to the optimal driving level. In particular, the storage controller 12 determines an average of the maximum delay value and the minimum delay value as the reference delay value.

To sum up, for the method of setting the signal drive strength of the storage 1 to one of the predefined driving levels according to the disclosure, the storage controller 12 of the storage 1 implements the test procedure for each of the predefined driving levels to determine a maximum delay value that is used to change a phase of a clock signal according to which the storage 1 correctly implements data-writing and data-reading, to determine a minimum delay value that is used to change the phase of the clock signal according to which the storage 1 correctly implements data-writing and data-reading, and to obtain a difference between the maximum delay value and the minimum delay value. Thereafter, according to the differences that are obtained respectively for the predefined driving levels, the storage controller 12 automatically selects one of the predefined driving levels as an optimal driving level that corresponds to a greatest one of the differences, and sets the signal drive strength of the storage 1 to the optimal driving level thus selected. In this way, an impact of temperature fluctuation on the storage 1 may be alleviated, thereby reducing the bit error rate (BER) in signal transmission of the storage 1 and enhancing operational stability of the storage 1.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is(are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A method of setting a signal drive strength of a storage to one of multiple predefined driving levels, adapted to be implemented by the storage, the method comprising steps of:
for each of the predefined driving levels, executing a test procedure that includes
implementing signal delay by changing a phase of a clock signal based on a plurality of delay values,
determining a maximum delay value that is used to change the phase of the clock signal according to which the storage correctly implements data-writing and data-reading,
determining a minimum delay value that is used to change the phase of the clock signal according to which the storage correctly implements data-writing and data-reading, and
obtaining a difference between the maximum delay value and the minimum delay value;
according to the differences that are obtained respectively for the predefined driving levels, selecting one of the predefined driving levels as an optimal driving level that corresponds to a greatest one of the differences; and
setting the signal drive strength of the storage to the optimal driving level thus selected.

2. The method as claimed in claim 1, further comprising:
determining whether the signal drive strength has been set to each of the predefined driving levels;
in response to determining that the signal drive strength has not been set to each of the predefined driving levels, implementing the step of executing a test procedure that further includes, before implementing signal delay, setting the signal drive strength to an unused one of the predefined driving levels to which the signal drive strength has not been set; and
in response to determining that the signal drive strength has been set to each of the predefined driving levels, implementing the steps of selecting an optimal driving level and setting the signal drive strength to the optimal driving level.

3. The method as claimed in claim 2, the storage including a storage controller and a storage medium electrically connected to the storage controller, wherein the test procedure further includes sub-steps of:
a) after setting the signal drive strength to the unused one of the predefined driving levels, designating a current value of a delay count as a default value that is not less than zero;
b) increasing the current value of the delay count and then changing the phase of the clock signal based on the current value of the delay count;
c) after sub-step b, determining whether or not the storage controller correctly implements data-writing into the storage medium and data-reading from the storage medium according to the clock signal;
d) in response to determining that the storage controller does not correctly implement data-writing into the storage medium and data-reading from the storage medium according to the clock signal, repeating sub-steps b and c; and
e) in response to determining that the storage controller correctly implements data-writing into the storage medium and data-reading from the storage medium according to the clock signal,
e1) making the current value of the delay count that is currently obtained in sub-step b serve as the minimum delay value,
e2) increasing the current value of the delay count, and then changing the phase of the clock signal based on the current value of the delay count,
e3) after sub-step e2, determining whether or not the storage controller correctly implements data-writing into the storage medium and data-reading from the storage medium according to the clock signal,
e4) in response to determining that the storage controller correctly implements data-writing into the storage medium and data-reading from the storage medium according to the clock signal, repeating sub-steps e2 and e3, and
e5) in response to determining that the storage controller does not correctly implement data-writing into the storage medium and data-reading from the storage medium according to the clock signal, making the current value of the delay count that was obtained in last execution of sub-step e2 serve as the maximum delay value.

4. The method as claimed in claim 3, the storage controller having the signal drive strength and being configured to communicate with an external device with the signal drive strength, wherein each of sub-steps c and e3 includes:
the storage controller obtaining test data from the external device with the signal drive strength of the predefined driving level;
the storage controller performing a memory test on the storage medium based on the test data to obtain a total number of error bits that have occurred during data-writing and data-reading by the storage controller according to the clock signal;
the storage controller determining whether the total number of error bits is greater than a predefined threshold;
in response to determining that the total number of error bits is not greater than the predefined threshold, the storage controller determining that data-writing into the storage medium and data-reading from the storage medium are correctly implemented; and
in response to determining that the total number of error bits is greater than the predefined threshold, the storage controller determining that data-writing into the storage medium and data-reading from the storage medium are not correctly implemented.

5. The method as claimed in claim 4, wherein the predefined threshold is zero.

6. The method as claimed in claim 3, wherein the default value is zero.

7. The method as claimed in claim 3, wherein, in sub-steps b and e2, increasing the current value of the delay count is to increase the current value of the delay count by one.

8. The method as claimed in claim 2, the predefined driving levels being sequentially arranged in an ascending order,
wherein the step of setting the signal drive strength to an unused one of the predefined driving levels is to set the signal drive strength to the unused one of the predefined driving levels to which the signal drive strength has not been set and which is a lowest one of the predefined driving levels in the ascending order.

9. The method as claimed in claim 2, the predefined driving levels being sequentially arranged in a descending order,
wherein the step of setting the signal drive strength to an unused one of the predefined driving levels is to set the signal drive strength to the unused one of the predefined driving levels to which the signal drive strength has not been set and which is a highest one of the predefined driving levels in the descending order.

10. The method as claimed in claim 1, further comprising determining a reference delay value based on the maximum delay value and the minimum delay value that correspond to the optimal driving level.

11. The method as claimed in claim 10, wherein determining a reference delay value is to determine an average of the maximum delay value and the minimum delay value as the reference delay value.
